(19) United States
(12) Patent Application Publication
(10) Pub. No.: US 2025/0239500 A1
(43) Pub. Date: Jul. 24, 2025

(54) LAMINATION STRUCTURE MANUFACTURED BY LASER PATTERNING

(71) Applicant: PANJIT INTERNATIONAL INC., Kaohsiung City (TW)

(72) Inventors: Chung Hsiung HO, Kaohsiung City (TW); Shan De YANG, Taichung City (TW)

(73) Assignee: PANJIT INTERNATIONAL INC., Kaohsiung City (TW)

(21) Appl. No.: 18/614,326

(22) Filed: Mar. 22, 2024

(30) Foreign Application Priority Data
Jan. 24, 2024 (TW) 113102745

(51) Int. Cl. H01L 23/31; H01L 23/00; H01L 23/522

(52) U.S. Cl. CPC H01L 23/3185; H01L 23/522; H01L 24/03; H01L 24/05; H01L 24/11; H01L 24/13; H01L 2224/03614; H01L 2224/0363; H01L 2224/05073; H01L 2224/05139; H01L 2224/05147; H01L 2224/05573; H01L 2224/11614; H01L 2224/1163; H01L 2224/13082; H01L 2224/13139; H01L 2224/13147

(57) ABSTRACT

A lamination structure including a substrate, a first metal pattern layer, a molding layer and a second metal pattern layer. The first metal pattern layer is formed on the substrate. At least a part of the molding layer and the first metal pattern layer are located on a layer. The second metal pattern layer is formed on the first metal pattern layer and has an opening pattern exposing the molding layer. The second metal pattern layer has a top part and a bottom part that are opposite to each other. The top part and the bottom part each have a rounded corner on an edge adjacent to the opening pattern.

### CROSS-REFERENCE TO RELATED APPLICATIONS

This non-provisional application claims priority under 35 U.S.C. § 119(a) on Patent Application No(s). 113102745 filed in Taiwan, R.O.C. on Jan. 24, 2024, the entire contents of which are hereby incorporated by reference.

### TECHNICAL FIELD

The disclosure relates to a lamination structure, more particularly to a lamination structure formed by a patterning process without using mask.

### BACKGROUND

In manufacturing a semiconductor or a circuit board, a lamination structure is widely used to electrically connect components on different regions or to prepare a wiring meeting the requirements of the product. In general, the formation of the lamination structure involves the patterning of a metal layer or a non-metal layer. In conventional manufacturing process, the formation of the lamination structure usually includes a photolithograph process of patterning one or more layers. However, the steps in the photolithograph process are complex, which is unfavorable for the reduction of the manufacture cost.

In response to the development of the advanced manufacturing, a laser micro-processing technique using laser direct structuring (LDS) (may be referred as laser engraving) to pattern one or more layers gradually draws attention due to the advantage of simplified process with fewer steps and low manufacture cost. However, the application of the laser direct structuring is restricted. For example, in order to prevent the laser from penetrating through the lamination structure, the lamination structure is required to include a barrier layer that cannot be removed by the energy of the laser to allow the laser direct structuring to be applied thereon.

### SUMMARY

Upon the above problems, the disclosure provides a lamination structure preventing the application of using the laser direct structuring to pattern one or more layers from being restricted.

One embodiment of this disclosure provides a lamination structure including a substrate, a first metal pattern layer, a molding layer and a second metal pattern layer. The first metal pattern layer is formed on the substrate. At least a part of the molding layer and the first metal pattern layer are located on a layer. The second metal pattern layer is formed on the first metal pattern layer and has an opening pattern exposing the molding layer. The second metal pattern layer has a top part and a bottom part that are opposite to each other. The top part and the bottom part each have a rounded corner on an edge adjacent to the opening pattern.

According to the embodiments of the disclosure, the metal layer is patterned by laser processing (or may be referred as laser engraving), and thus the photolithography process using one or more masks is allowed to be omitted, thereby simplifying the process and reducing the manufacture cost. Further, the opening pattern is formed by performing wet etching on the metal layer where the laser processing has been performed, and thus the laser beam is prevented from striking the molding layer or even the semiconductor unit, thereby preventing the laser beam from damaging the molding layer or even the semiconductor unit. In addition, since wet etching is used as the final step in the overall patterning process, the rounded corners may be formed on the edge of the second metal pattern layer adjacent to the opening pattern.

### BRIEF DESCRIPTION OF THE DRAWINGS

The present disclosure will become better understood from the detailed description given herein below and the accompanying drawings which are given by way of illustration only and thus are not intending to limit the present disclosure and wherein:

FIG. 1 is a top schematic view of a lamination structure according to one embodiment of the disclosure;

FIG. 2 is a cross-sectional view of the lamination structure in FIG. 1 taken along line 2-2;

FIG. 3 is a partially enlarged view of the lamination structure in FIG. 2;

FIGS. 4 to 6 are schematic views showing a manufacture of the lamination structure in FIG. 2;

FIG. 7 is a cross-sectional view of a lamination structure according to another embodiment of the disclosure;

FIG. 8 is a partially enlarged view of the lamination structure in FIG. 7; and

FIGS. 9 and 10 are schematic views showing a manufacture of the lamination structure in FIG. 7.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

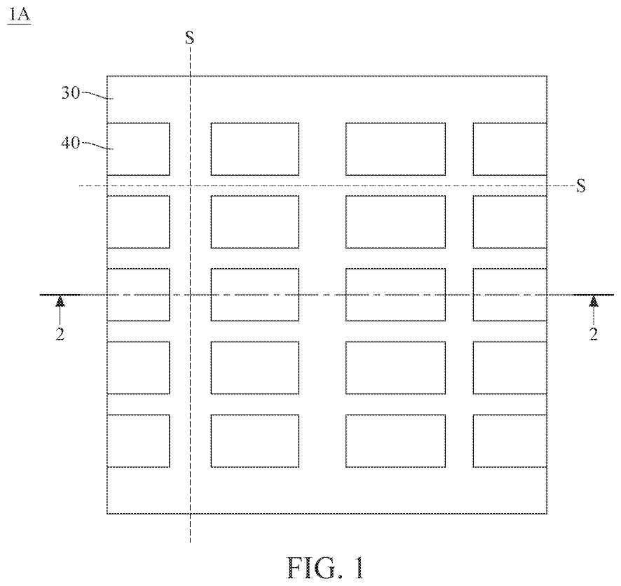

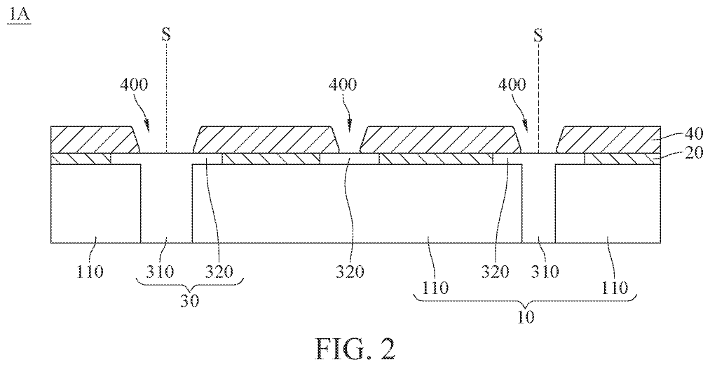

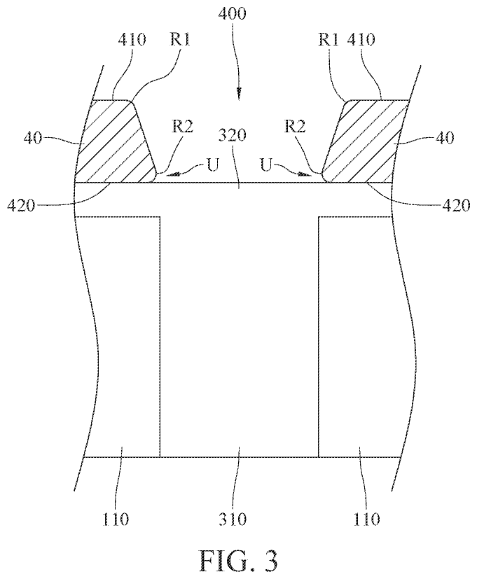

Please refer to FIGS. 1 to 3, where FIG. 1 is a top schematic view of a lamination structure 1A according to one embodiment of the disclosure, FIG. 2 is a cross-sectional view of the lamination structure 1A in FIG. 1 taken along line 2-2, and FIG. 3 is a partially enlarged view of the lamination structure 1A in FIG. 2. In this embodiment, the lamination structure 1A includes a substrate 10, a first metal pattern layer 20, a molding layer 30 and a second metal pattern layer 40. The lamination structure 1A may be a semiconductor package structure.

The substrate 10 may include a plurality of semiconductor units 110. The semiconductor units 110 may each be a die including a semiconductor material, such as a silicon, silicon carbide or III-V semiconductor. In this embodiment, the semiconductor units 110 are spaced apart from one another along a horizontal direction in FIG. 2.

The first metal pattern layer 20 is formed on the substrate 10. Further, the first metal pattern layer 20 may function as an electrical contact formed on a surface of the semiconductor unit 110. The first metal pattern layer 20 may include aluminum.

At least a part of the molding layer 30 and the first metal pattern layer 20 are located on the same layer. Further, the molding layer 30 includes a first molding part 310 and a second molding part 320. The first molding part 310 is located between two adjacent semiconductor units 110. That is, two adjacent semiconductor units 110 are spaced apart from each other by the first molding part 310 of the molding layer 30. The second molding part 320 and the first metal pattern layer 20 are located on the same layer. In addition, the molding layer 30 has a plurality of cutting channels S corresponding to a region between two adjacent semiconductor units 110. The molding layer 30 may include organic composite material, resin composite material, polymer composite material or any other types of solid molding compound. For example, the molding layer 30 may include epoxy.

The second metal pattern layer 40 is formed on the first metal pattern layer 20, and the second metal pattern layer 40 has an opening pattern 400 exposing the molding layer 30. Further, the second metal pattern layer 40 may function as a pad or a bump formed on the semiconductor unit 110. The second metal pattern layer 40 has a top part 410 and a bottom part 420 that are opposite to each other. In this embodiment, the top part 410 and the bottom part 420 may be understood as a top surface and a bottom surface of the second metal pattern layer 40, respectively. Alternatively, the top part 410 and the bottom part 420 may be understood as a half part of the second metal pattern layer 40 located on a top side thereof and a half part of the second metal pattern layer 40 located on a bottom side thereof, respectively. The opening pattern 400 exposes the second molding part 320 of the molding layer 30. The top part 410 has a rounded corner R1 on an edge adjacent to the opening pattern 400, and the bottom part 420 has a rounded corner R2 on an edge adjacent to the opening pattern 400. Further, the rounded corners R1 and R2 may each be a bullnose. Due to the rounded corner R2, an undercut U may be formed between the bottom part 420 of the second metal pattern layer 40 and the second molding part 320 of the molding layer 30. The undercut U is formed by etching the bottom part 420 of the second metal pattern layer 40 inwardly via wet etching, and the undercut U has the rounded corner R2 protruding toward the opening pattern 400. The second metal pattern layer 40 may include copper.

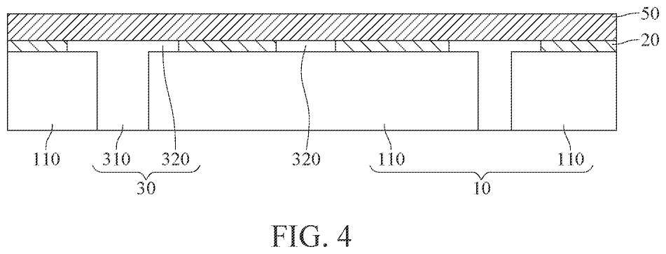

Hereinafter, a manufacturing method of the lamination structure 1A in FIG. 2 will be described. FIGS. 4 to 6 are schematic views showing a manufacture of the lamination structure 1A in FIG. 2. As shown in FIG. 4, a lamination structure including the substrate 10, the first metal pattern layer 20, the molding layer 30 and a metal layer 50 is provided. The metal layer 50 is, for example, a copper layer that can be processed into the second metal pattern layer 40, which will be further described below.

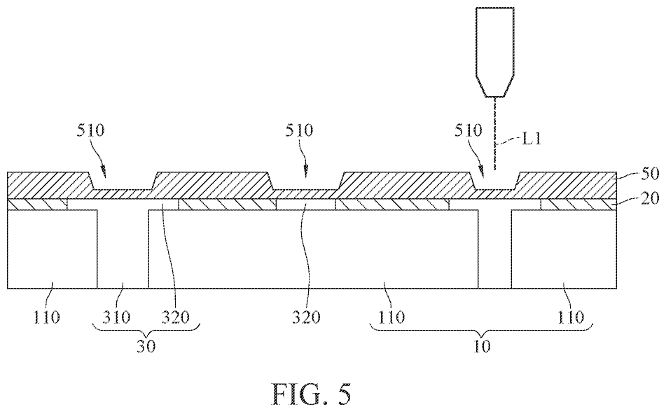

As shown in FIG. 5, a laser patterning is performed on the metal layer 50 to form a tapered pattern or a strip pattern on the metal layer 50. In detail, the absorptance of the surface of the metal layer 50 in absorbing the energy of the laser beam L1 is high enough to allow the laser beam L1 to strike the metal layer 50, such that tapered recesses 510 are formed on the metal layer 50. Specifically, by performing a half cut on the metal layer 50 via the laser beam L1, the laser beam L1 does not strike the molding layer 30 located below the metal layer 50.

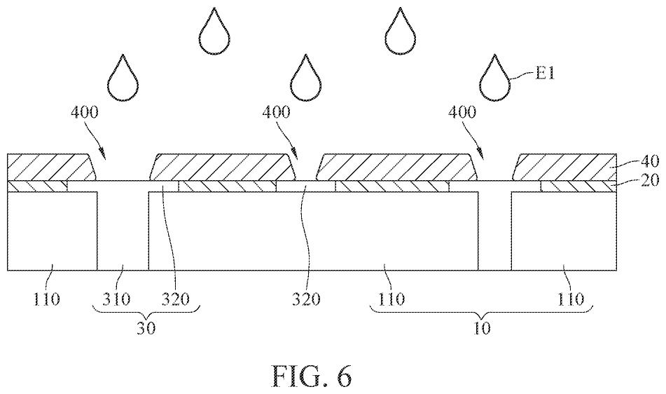

As shown in FIG. 6, a wet etching is further performed on the metal layer 50 to form the second metal pattern layer 40. In detail, a first liquid etchant E1 is diffused to the metal layer 50 so that the recesses 510 in FIG. 5 become a plurality of opening patterns 400 exposing the second molding part 320 of the molding layer 30. In a case that the metal layer 50 is a copper layer, the first liquid etchant E1 is a copper etchant, such as, but not limited to, phosphoric acid, sulfuric acid, copper chloride or ferric chloride; in a case that the metal layer 50 is a silver layer, the first liquid etchant E1 is a silver etchant. In this embodiment, since wet etching is used as the final step in the overall patterning process shown in FIGS. 5 and 6, the rounded corners R1 and R2 may be formed on the edge of the second metal pattern layer 40 adjacent to the opening pattern 400.

The lamination structure 1A is selectively cut along, for example, the cutting channels S shown in FIGS. 1 and 2, so as to obtain a plurality of semiconductor components including pads or bumps.

According to the embodiments of the disclosure, the metal layer 50 is patterned by laser micro-processing (or may be referred as laser engraving), and thus the photolithography process using one or more masks is allowed to be omitted, thereby simplifying the process and reducing the manufacture cost. Further, the opening pattern 400 is formed by performing wet etching on the metal layer 50 where the laser micro-processing has been performed, and thus the laser beam is prevented from striking the molding layer 30 or even the semiconductor unit 110, thereby preventing the laser beam from damaging the molding layer 30 or even the semiconductor unit 110.

In the top view of the lamination structure 1A in FIG. 1, the second metal pattern layer 40 includes a plurality of metal pads or metal bumps arranged in an array, but the disclosure is not limited by this specific configuration. In other embodiments, in the top view, the second metal pattern layer may further include bridges parts each connecting two metal pads or meal bumps.

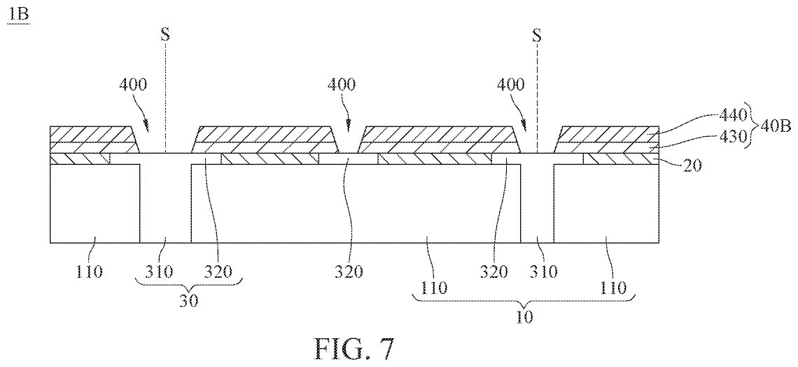

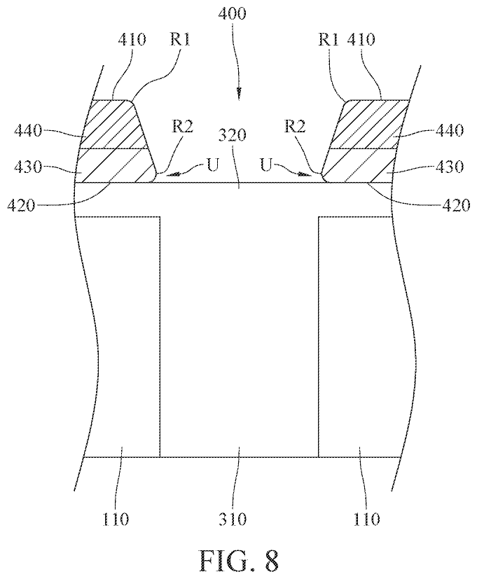

The lamination structure disclosed by the disclosure is not limited to the configuration shown in FIG. 1. Please refer to FIGS. 7 and 8, where FIG. 7 is a cross-sectional view of a lamination structure 1B according to another embodiment of the disclosure, and FIG. 8 is a partially enlarged view of the lamination structure 1B in FIG. 7. In this embodiment, the lamination structure 1B includes the substrate 10, the first metal pattern layer 20, the molding layer 30 and a second metal pattern layer 40B. Please refer to the relevant descriptions of the lamination structure 1A shown in FIG. 1 for the detailed descriptions regarding the substrate 10, the first metal pattern layer 20 and the molding layer 30, and the repeated descriptions are omitted. Hereinafter, the difference between the lamination structure 1B and the lamination structure 1A will be mainly described.

The second metal pattern layer 40B of the lamination structure 1B includes a first metal sublayer 430 and a second metal sublayer 440. The first metal sublayer 430 is located between the second metal sublayer 440 and the first metal pattern layer 20. The first metal sublayer 430 and the second metal sublayer 440 together form the opening patterns 400. The first metal sublayer 430 has a bottom part 420 of the second metal pattern layer 40B, and the second metal sublayer 440 has a top part 410 of the second metal pattern layer 40B. The first metal sublayer 430 and the second metal sublayer 440 may be made by different metal materials, and the second metal sublayer 440 and the first metal pattern layer 20 may be made by the same metal material. In this embodiment, the first metal sublayer 430 may include aluminum. Additionally, the second metal sublayer 440 and the first metal pattern layer 20 may include copper.

The opening patterns 400 exposes the second molding part 320 of the molding layer 30. The top part 410 of the second metal sublayer 440 has the rounded corner R1 on an edge adjacent to the opening pattern 400, and the bottom part 420 of the first metal sublayer 430 has the rounded corner R2 on an edge adjacent to the opening pattern 400. Further, the rounded corners R1 and R2 may each be a bullnose. Due to the rounded corner R2, the undercut U may be formed between the bottom part 420 of the first metal sublayer 430 and the second molding part 320 of the molding layer 30. The undercut U is formed by etching the bottom part 420 of the first metal sublayer 430 inwardly via wet etching, and the undercut U has the rounded corner R2 protruding toward the opening pattern 400.

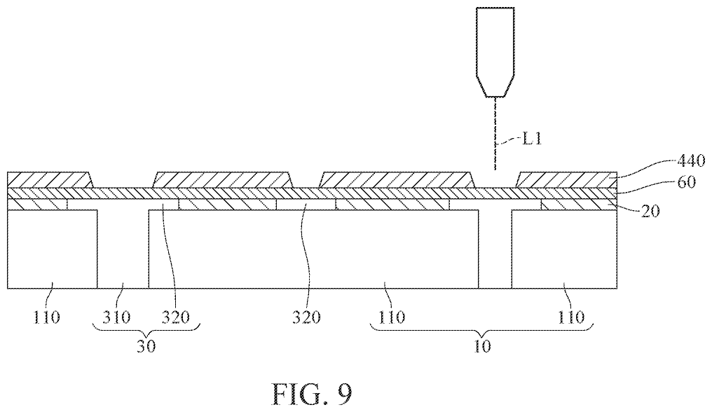

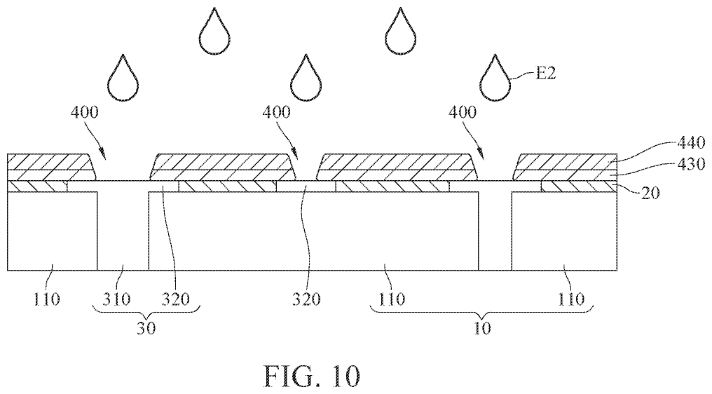

FIGS. 9 and 10 are schematic views showing a manufacture of the lamination structure 1B in FIG. 7. As shown in FIG. 9, a laser patterning is performed on the metal layer. Further, the laser beam L1 strikes the metal layer (e.g., copper layer) to from the second metal sublayer 440. Specifically, the laser beam L1 may be a laser with a wavelength ranging from 0.2 micrometer to 0.4 micrometer. The absorptance of the surface of the metal layer for forming the second metal sublayer 440 in absorbing the energy of the laser beam L1 may be 60% or more. In some embodiments, the absorptance of the surface of the metal layer for forming the second metal sublayer 440 in absorbing the energy of the laser beam L1 may be 70% or more. In some embodiments, the absorptance of the surface of the metal layer for forming the second metal sublayer 440 in absorbing the energy of the laser beam L1 may be 75% or more.

In this embodiment, the absorptance of the surface of the first metal sublayer 430 and the absorptance of the surface of the second metal sublayer 440 in absorbing the laser beam with specific wavelength may be different from each other. In detail, the absorptance of the surface of the metal layer for forming the second metal sublayer 440 in absorbing the laser beam L1 may be higher than the absorptance of the surface of the metal layer 60 for forming the first metal sublayer 430 in absorbing the laser beam L1. Thus, the efficiency of the laser processing is enhanced and the metal layer 60 having lower absorptance functions as a barrier layer for laser processing. Specifically, with respect to the laser beam L1 with a wavelength ranging from 0.2 micrometer to 0.4 micrometer, the absorptance of the surface of the metal layer 60 for forming the first metal sublayer 430 may be 50% or less. In some embodiments, the absorptance of the surface of the metal layer 60 for forming the first metal sublayer 430 may be 40% or less. In some embodiments, the absorptance of the surface of the metal layer 60 for forming the first metal sublayer 430 may be 30% or less.

The specific magnitude of the wavelength of the laser beam and that of the absorptance mentioned above are exemplary, and the disclosure is not limited thereto.

As shown in FIG. 10, to form the first metal sublayer 430, a wet etching is further performed on the metal layer 60 for forming the first metal sublayer 430. In detail, a second liquid etchant E2 may be diffused to the metal layer 60 to form the opening patterns 400 exposing the second molding part 320 of the molding layer 30. In a case that the first metal sublayer 430 and the second metal sublayer 440 are made by different metal materials, the second liquid etchant E2 has specific selectivity to the first metal sublayer 430 and the second metal sublayer 440, such that the second liquid etchant E2 only etches the first metal sublayer 430 but does not etch the second metal sublayer 440. In a case that the first metal sublayer 430 is an aluminum layer, the second liquid etchant E2 is an aluminum etchant. In this embodiment, since the wet etching is used as the final step in the overall patterning process shown in FIGS. 9 and 10, the rounded corners R1 and R2 may be formed on the edges of the first metal sublayer 430 and the second metal sublayer 440 adjacent to the opening pattern 400.

The lamination structure 1B may be selectively cut along, for example, the cutting channels S shown in FIG. 7, so as to obtain a plurality of semiconductor components including pads or bumps.

As discussed above, according to the embodiments of the disclosure, the metal layer is patterned by laser processing (or may be referred as laser engraving), and thus the photolithography process using one or more masks is allowed to be omitted, thereby simplifying the process and reducing the manufacture cost. Further, the opening pattern is formed by performing wet etching on the metal layer where the laser processing has been performed, and thus the laser beam is prevented from striking the molding layer or even the semiconductor unit, thereby preventing the laser beam from damaging the molding layer or even the semiconductor unit. In addition, since wet etching is used as the final step in the overall patterning process, the rounded corners may be formed on the edge of the second metal pattern layer adjacent to the opening pattern.

It will be apparent to those skilled in the art that various modifications and variations can be made to the present disclosure. It is intended that the specification and examples be considered as exemplary embodiments only, with a scope of the disclosure being indicated by the following claims and their equivalents.

What is claimed is:

1. A lamination structure, comprising:
a substrate;
a first metal pattern layer, formed on the substrate;
a molding layer, wherein at least a part of the molding layer and the first metal pattern layer are located on a layer; and
a second metal pattern layer, formed on the first metal pattern layer and having an opening pattern exposing the molding layer; and
wherein, the second metal pattern layer has a top part and a bottom part that are opposite to each other, and the top part and the bottom part each have a rounded corner on an edge adjacent to the opening pattern.

2. The lamination structure according to claim 1, wherein the substrate comprises a plurality of semiconductor units, two adjacent ones of the plurality of semiconductor units are spaced apart from each other by the molding layer, and the molding layer has at least one cutting channel.

3. The lamination structure according to claim 2, wherein the molding layer comprises a first molding part and a second molding part, the first molding part is located between two adjacent ones of the plurality of semiconductor units, the second molding part and the first metal pattern layer are located on a layer, and the opening pattern exposes the second molding part.

4. The lamination structure according to claim 1, wherein the second metal pattern layer is formed by laser patterning and wet etching.

5. The lamination structure according to claim 1, wherein the second metal pattern layer comprises a first metal sublayer and a second metal sublayer made by different metal materials, the first metal sublayer is located between the second metal sublayer and the first metal pattern layer, and the first metal sublayer and the second metal sublayer together form the opening pattern.

6. The lamination structure according to claim 5, wherein the second metal sublayer and the first metal pattern layer of the second metal pattern layer are made by a metal material.

7. The lamination structure according to claim 5, wherein the first metal sublayer has the bottom part, and the second metal sublayer has the top part.

8. The lamination structure according to claim 5, wherein the second metal sublayer is formed by laser patterning and the first metal sublayer is formed by wet etching.

9. The lamination structure according to claim 8, wherein with respect to a laser beam with a specific wavelength, an absorptance of the first metal sublayer is different from an absorptance of the second metal sublayer.

10. The lamination structure according to claim 9, wherein with respect to the laser beam with the specific wavelength, the absorptance of the second metal sublayer is higher than the absorptance of the first metal sublayer.
